(19) United States
(12) Patent Application Publication
(10) Pub. No.: US 2018/0203344 A1
(43) Pub. Date: Jul. 19, 2018

(54) PHOTOMASK

(71) Applicant: UNITED MICROELECTRONICS CORP., Hsin-Chu City (TW)

(72) Inventors: En-Chiuan Liou, Tainan City (TW); Yu-Cheng Tung, Kaohsiung City (TW); Chia-Hung Lin, Tainan City (TW)

(21) Appl. No.: 15/436,764

(22) Filed: Feb. 18, 2017

(30) Foreign Application Priority Data
Jan. 17, 2017 (TW) 106101499

(51) Int. Cl. G03F 1/58; G03F 1/54

(52) U.S. Cl. CPC G03F 1/58; G03F 1/54

(57) ABSTRACT

A photomask includes a substrate, a patterned absorber layer disposed on the substrate, and a plurality of openings. Each of the openings penetrates the patterned absorber layer and exposes a part of the substrate. At least two of the openings are disposed adjacent to each other in a first direction. At least a part of the patterned absorber layer disposed between the two adjacent openings in the first direction has a first thickness. A part of the patterned absorber layer disposed at two opposite edges of each of the openings in a second direction different from the first direction has a second thickness. Another part of the patterned absorber layer disposed at the two opposite edges of each of the openings in the second direction has a third thickness. The first thickness is equal to the second thickness, and the first thickness is different from the third thickness.

### BACKGROUND OF THE INVENTION

### 1. Field of the Invention

The present invention relates to a photomask, and more particularly, to a photomask having a patterned absorber layer with different thicknesses.

### 2. Description of the Prior Art

With the advancement of technology, the semiconductor processes are refined continuously. A modern chip is allowed to have a plurality of various electronic circuits configured within. The semiconductor manufacturing processes for manufacturing the chip may include many steps, such as deposition processes for forming thin films, photoresist coating processes, exposure processes, and develop processes for forming patterned photoresists, and etching processes for patterning the thin films. As the integrity of the integrated circuit increases, the dimensions of the devices in the integrated circuit become smaller. Accordingly, exposure technologies with higher resolution are steadily developed for manufacturing circuits with smaller feature dimensions. However, the exposure resolution enhancement is limited when methods, such as reducing wavelength of light source or modifying optical systems for increasing the numerical aperture (N.A.), are applied, and it is necessary to modify the design of photomask for realizing the manufacture of devices with smaller feature dimensions.

### SUMMARY OF THE INVENTION

A photomask is provided in the present invention. A patterned absorber layer with different thickness distribution is disposed in the photomask for modifying the focus length at regions between adjacent openings during the exposure process. The problem of unable to form the pattern corresponding to regions between adjacent openings after the exposure and the develop processes when the adjacent openings are extremely close to one another may be avoided accordingly, and the purpose of enhancing the resolution of the photolithographic process may be achieved.

A photomask is provided in an embodiment of the present invention. The photomask includes a substrate, a patterned absorber layer, and a plurality of openings. The patterned absorber layer is disposed on the substrate, and each of the openings penetrates the patterned absorber layer and exposes apart of the substrate. At least two of the openings are disposed adjacent to each other in a first direction. At least a part of the patterned absorber layer disposed between the two adjacent openings in the first direction has a first thickness. A part of the patterned absorber layer disposed at two opposite edges of each of the openings in a second direction different from the first direction has a second thickness. Another part of the patterned absorber layer disposed at the two opposite edges of each of the openings in the second direction has a third thickness. The first thickness is equal to the second thickness, and the first thickness is different from the third thickness.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top-view diagram illustrating a photomask according to a first embodiment of the present invention.

FIG. 2 is a cross-sectional diagram taken along a line A-A′ in FIG. 1.

FIG. 3 is a cross-sectional diagram taken along a line B-B′ in FIG. 1.

FIG. 4 is a cross-sectional diagram taken along a line C-C′ in FIG. 1.

FIG. 5 is a diagram illustrating a performance comparison between a result of a photolithographic process using the photomask of the first embodiment of the present invention and a result of a photolithographic process using the conventional photomask.

FIG. 6 is a schematic drawing illustrating a photomask according to a second embodiment of the present invention.

FIG. 7 is a top-view diagram illustrating a photomask according to a third embodiment of the present invention.

FIG. 8 is a cross-sectional diagram taken along a line D-D′ in FIG. 7.

FIG. 9 is a top-view diagram illustrating a photomask according to a fourth embodiment of the present invention.

### DETAILED DESCRIPTION

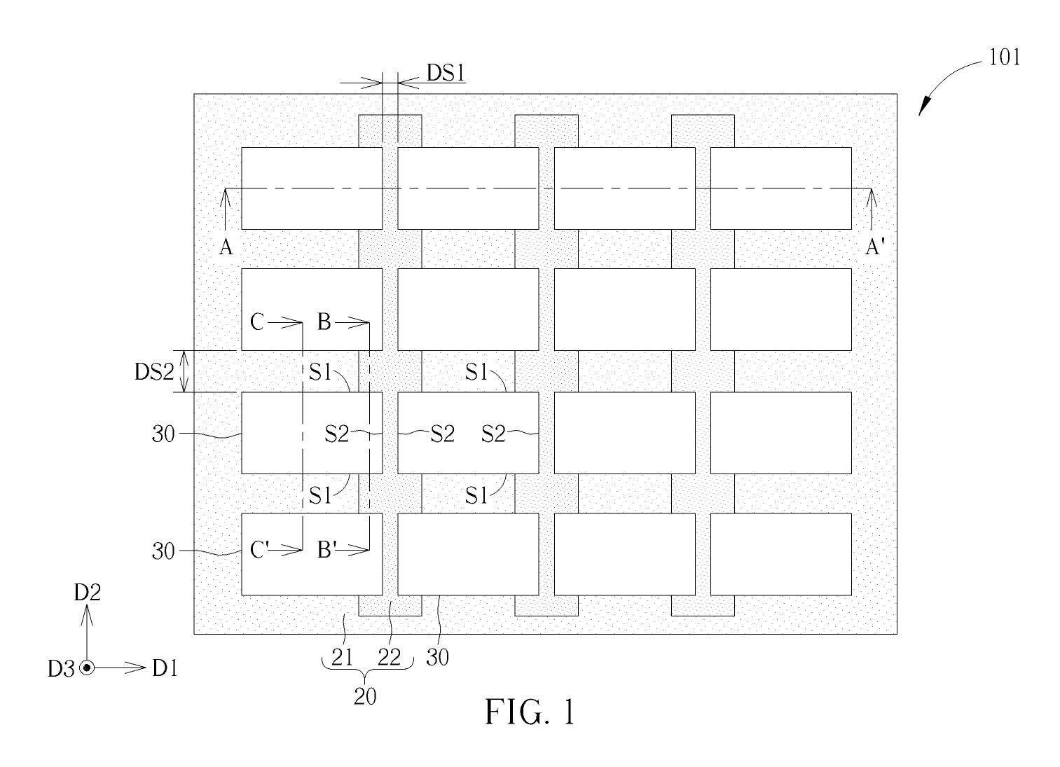

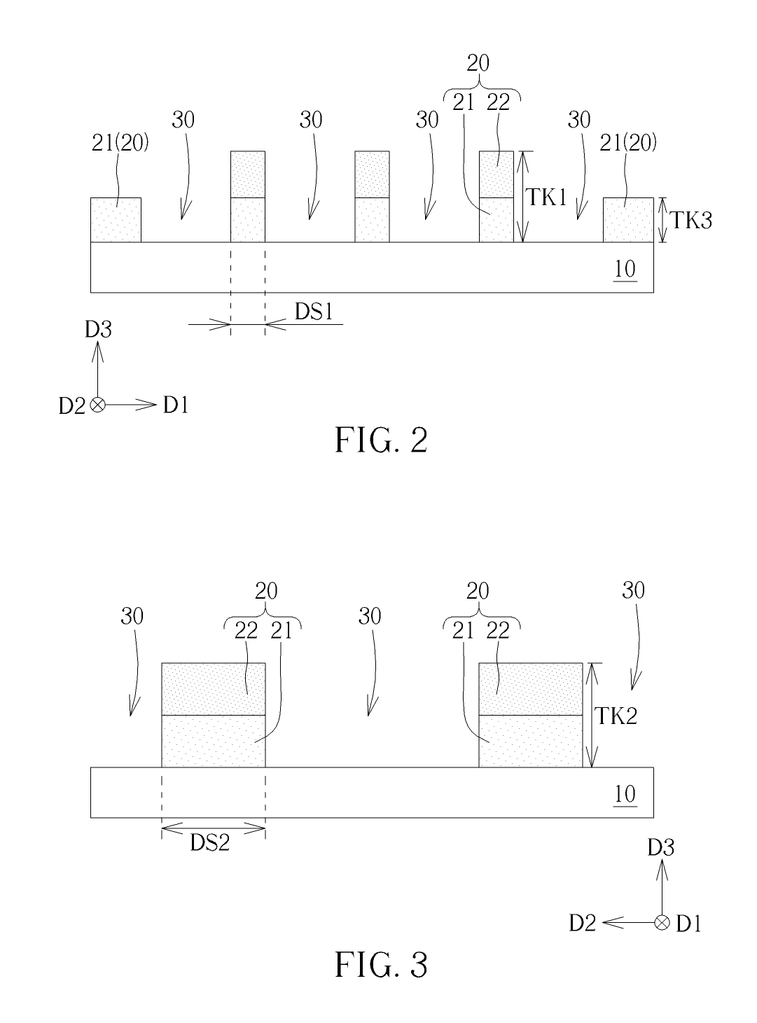

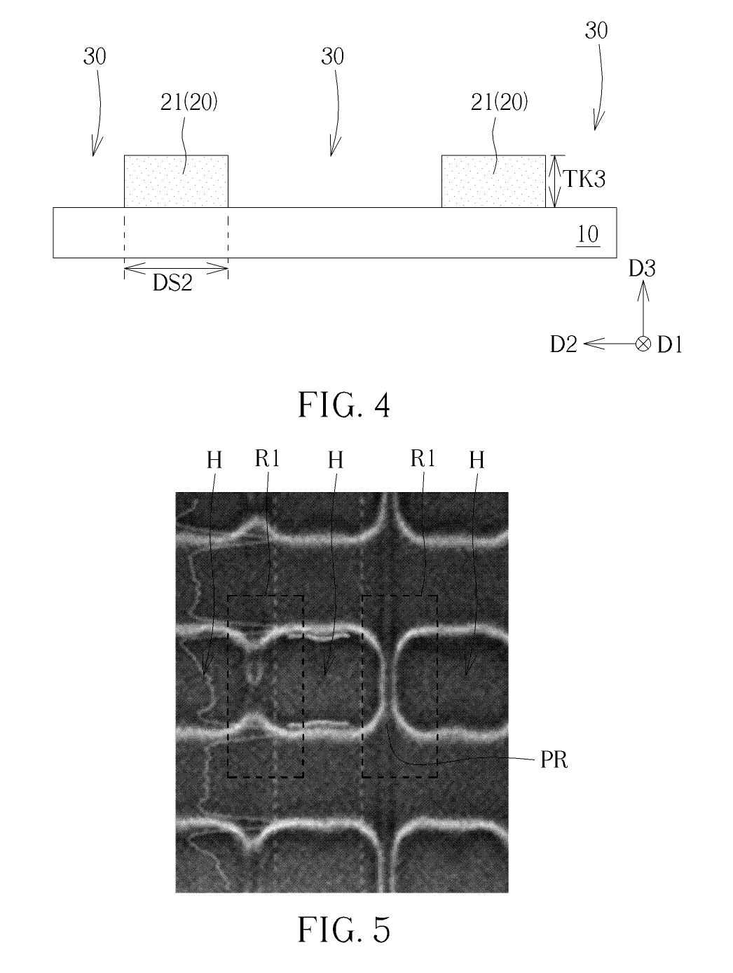

Please refer to FIGS. 1-5. FIG. 1 is a top-view diagram illustrating a photomask according to a first embodiment of the present invention. FIG. 2 is a cross-sectional diagram taken along a line A-A′ in FIG. 1. FIG. 3 is a cross-sectional diagram taken along a line B-B′ in FIG. 1. FIG. 4 is a cross-sectional diagram taken along a line C-C′ in FIG. 1. FIG. 5 is a diagram illustrating a performance comparison between a result of a photolithographic process using the photomask of this embodiment and a result of a photolithographic process using a conventional photomask. As shown in FIGS. 1-4, a photomask 101 is provided in this embodiment. The photomask 101 includes a substrate 10, a patterned absorber layer 20, and a plurality of openings 30. The substrate 10 may include a transparent substrate, such as a quartz substrate, a glass substrate, a plastic substrate, and a ceramic substrate, or substrates made of other suitable materials. The patterned absorber layer 20 may include light-absorbing materials, light-blocking materials, or other suitable materials capable of changing the light transmittance and/or the light path of the light source used in an exposure process with the photomask 101. For example, the patterned absorber layer 20 may include opaque materials such as chromium or resin, or translucent materials such as molybdenum silicide, but not limited thereto. Additionally, the composition ratio of materials in molybdenum silicide may be further modified for adjusting the light transmittance or being opaque. The patterned absorber layer 20 is disposed on the substrate 10, and each of the openings 30 penetrates the patterned absorber layer 20 and exposes a part of the substrate 10. When the photomask 101 and a positive photoresist are used in an exposure process and a develop process, the openings 30 of the photomask 101 may be used to form holes in the positive photoresist. Comparatively, when the photomask 101 and a negative photoresist are used in the exposure process and the develop process, the openings 30 of the photomask 101 may be corresponding to block patterns formed of the negative photoresist.

In this embodiment, at least two of the openings 30 may be disposed adjacent to each other in a first direction D1, and at least two of the openings 30 may be disposed adjacent to each other in a second direction D2. The second direction D2 is different from the first direction D1. In some embodiments, the first direction D1 and the second direction D2 may be substantially orthogonal to each other, but not limited thereto. A distance (such as a first distance DS1 shown in FIG. 1) between the two adjacent openings 30 in the first direction D1 is smaller than a distance (such as a second distance DS2 shown in FIG. 1) between the two adjacent openings 30 in the second direction D2. In other words, at least two of the openings 30 are closer to each other in the first direction D1. In addition, at least a part of the patterned absorber layer 20 disposed between the two adjacent openings 20 in the first direction D1 has a first thickness TK1. A part of the patterned absorber layer 20 disposed at two opposite edges (such as two first edge S1 shown in FIG. 1) of each of the openings 30 in the second direction D2 has a second thickness TK2, and another part of the patterned absorber layer 20 disposed at the two opposite edges of each of the openings 30 in the second direction D2 has a third thickness TK3. The first thickness TK1 is equal to the second thickness TK2, and the first thickness TK1 is different from the third thickness TK3. In other words, a thickness of at least a part of the patterned absorber layer 20 disposed between two adjacent openings 30 which are relatively closer to each other is different from a thickness of at least a part of the patterned absorber layer 20 disposed between two adjacent openings 30 which are relatively far from each other, and the part of the patterned absorber layer 20 with the second thickness TK2 equal to the first thickness TK1 also extends to be disposed between two adjacent openings 30 which are relatively far from each other. The thickness distribution of the patterned absorber layer 20 in different regions may be used to modify the focus length at the region between two adjacent openings 30 in the exposure process, the problem of unable to form the pattern corresponding to regions between adjacent openings 30 after the exposure and the develop processes when the adjacent openings 30 are extremely close to one another (such as when the first distance DS1 mentioned above is smaller than the resolution limitation of the exposure process) may be avoided accordingly, and the purpose of enhancing the resolution of the photolithographic process may be achieved.

For example, in the patterned absorber layer 20 of the present embodiment, the first thickness TK1 may be larger than the third thickness TK3. In other words, the thickness of at least a part of the patterned absorber layer 20 disposed between two adjacent openings 30 which are relatively closer to each other is larger than a thickness of at least a part of the patterned absorber layer 20 disposed between two adjacent openings 30 which are relatively far from each other, and the part of the patterned absorber layer 20 with the second thickness TK2 equal to the first thickness TK1 also extends to be disposed between two adjacent openings 30 which are relatively far from each other, but the present invention is not limited to this. In some embodiments, the first thickness TK1 may be smaller than the third thickness TK3 for being employed in an appropriate exposure method and generating demanded exposure effects. Additionally, the part of the patterned absorber layer 20 having the relatively thicker first thickness TK and second thickness TK2 surrounds at least one edge (such as a second edge S2 shown in FIG. 1) of each of the openings 30 in the first direction D1 and extends to be disposed at a part of the first edge S1. In some embodiments, the patterned absorber layer 20 disposed between two adjacent openings 30 in the first direction D1 may have the first thickness TK1 only, but not limited thereto. In some embodiments, when a distance between two adjacent openings 30 is smaller than the resolution limitation of the exposure process, a thickness of at least a part of the patterned absorber layer 20 disposed between the two adjacent openings is different from a thickness of the patterned absorber layer 20 disposed in other regions.

As shown in FIGS. 1-4, in some embodiments, the patterned absorber layer 20 may include a first patterned layer 21 and a second patterned layer 22. The first patterned layer 21 is disposed on the substrate 10, and the second patterned layer 22 is disposed on the first patterned layer 21 in a vertical direction D3. The second patterned layer 22 is partly disposed between the two adjacent openings 30 in the first direction D1 and partly disposed at the two opposite edges of each of the openings 30 in the second direction D2. In other words, the first patterned layer 21 and the second patterned layer may have different shapes and overlap with each other for forming the patterned absorber layer 20 having different thicknesses indifferent regions. The region of the patterned absorber layer 20 having the relatively thicker first thickness TK1 and second thickness TK2 may be formed by the first patterned layer 21 and the second patterned layer 22 overlapping each other, and the region of the patterned absorber layer 20 having the relatively thinner third thickness TK3 maybe formed by the region of the first patterned layer 21 which is not covered by the second patterned layer 22, but not limited thereto. In some embodiments, the material of the first patterned layer 21 may be different from the material of the second patterned layer 22. For example, the first patterned layer 21 may include molybdenum silicide, and the second patterned layer 22 may include chromium, but not limited thereto. In some other embodiments, the first patterned layer 21 and the second patterned layer 22 may also be formed by other opaque or translucent materials according to other considerations. For example, the first patterned layer 21 may include chromium, and the second patterned layer 22 may include molybdenum silicide. Additionally, in some embodiments, the first patterned layer 21 and the second patterned layer 22 may also be formed by the same material according to some considerations. For example, the material of the first patterned layer 21 and the second patterned layer 22 may be molybdenum silicide, chromium, or resin, but not limited thereto. When the material of the first patterned layer 21 and the material of the second patterned layer 22 are the same, the first patterned layer 21 and the second patterned layer 22 may also be formed by some suitable patterning approaches, such as performing different etching processes to one material layer respectively.

In some embodiments, the first patterned layer 21 may surround each of the openings 30, and the second patterned layer 22 may be disposed at only a part of the edges of each of the openings 30. For example, the first patterned layer 21 may be disposed on the first edges S1 and the second edges S2 of each of the openings 30, the second patterned layer 22 may be disposed on the second edges S2 of at least a part of the openings 30, and the second patterned layer 22 extends to be disposed on a part of the first edges S1 of at least a part of the openings 30. In other words, a part of the first patterned layer 21 disposed on the edges of each opening 30 and disposed between the two adjacent openings in the second direction D2 is not covered by the second patterned layer 22. Additionally, as shown in FIG. 1 and FIG. 2, a width of the first patterned layer 21 disposed between the two adjacent openings 30 in the first direction D1 may be substantially equal to a width of the second patterned layer 22 disposed between the two adjacent openings 30 in the first direction D1, but not limited thereto. In the process of forming the patterned absorber layer 20, the second patterned layer 22 and a part of the first patterned layer 21 may be patterned simultaneously for generating self-aligned effects, but not limited thereto. Additionally, in some embodiments, the second patterned layer 22 may be disposed between plurality sets of adjacent openings 30, but not limited thereto.

The patterned absorber layer 20 having the different thickness distribution in the different regions in this embodiment may be used to modify the focus length at the region between two adjacent openings 30 in the exposure process, and the problem of unable to form the pattern corresponding to regions between adjacent openings 30 after the exposure and the develop processes when the adjacent openings 30 are extremely close to one another may be avoided accordingly. For example, please refer to FIG. 1 and FIG. 5. FIG. 5 is a diagram illustrating a performance comparison between a result of a photolithographic process using the photomask of this embodiment and a result of a photolithographic process using a conventional photomask. The conventional photomask is a photomask including a patterned absorber layer with a single and uniform thickness, and the dimensions and locations of openings in the patterned absorber layer of the conventional photomask are similar to those of the photomask 101 in this embodiment. A photoresist pattern after the exposure and develop processes is shown in FIG. 5, and holes H in FIG. 5 may be defined by the openings in the photomask 101 of this embodiment or the openings in the conventional photomask. Two of the holes H at the center and right parts of FIG. 5 may be regarded as the result of the photolithographic process using the photomask 101 of this embodiment, and two of the holes H at the center and left parts of FIG. 5 may be regarded as the result of the photolithographic process using the conventional photomask. According to the results shown in FIG. 5, when the distance between the openings is too small, the holes H will be directly connected with one another and the photoresist PR between the holes H will not remain (such as the condition shown within a first region R1 in FIG. 5) by applying the photomask including the patterned absorber layer with a single and uniform thickness. However, under the same exposure conditions, when the distance between the openings is too small, the photoresist PR between the holes H still remains and the required pattern may be obtained (such as the condition shown within a second region R2 in FIG. 5) by applying the photomask 101 of this embodiment in the photolithographic process. Accordingly, the patterned absorber layer 20 having the different thickness distribution in the different regions in this embodiment may be used to enhance the resolution of the photolithographic process.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

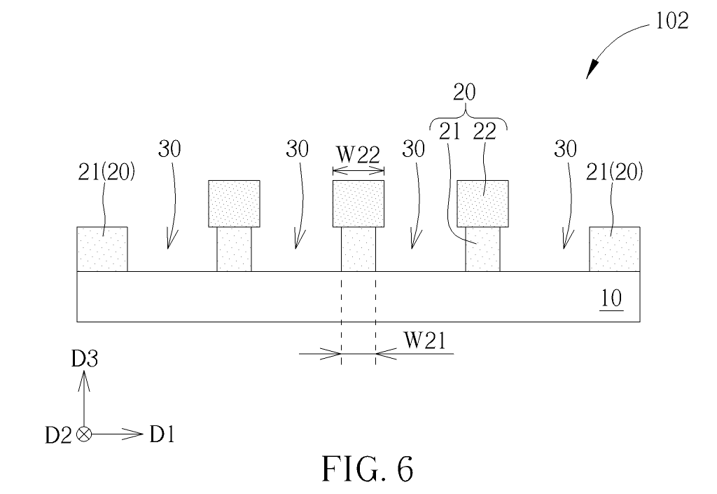

Please refer to FIG. 6. FIG. 6 is a schematic drawing illustrating a photomask 102 according to a second embodiment of the present invention. As shown in FIG. 6, the difference between the photomask 102 in this embodiment and the photomask in the first embodiment is that, in this embodiment, a width (such as a second width W22 shown in FIG. 6) of the second patterned layer 22 disposed between the two adjacent openings 30 in the first direction D1 is larger than a width (such as a first width W21 shown in FIG. 6) of the first patterned layer 21 disposed between the two adjacent openings 30 in the first direction D1. The wider part of the second patterned layer 22 may be used to further modify the focus length at the region between two adjacent openings 30 in the exposure process for ensuring obtaining the demanded pattern of the photoresist.

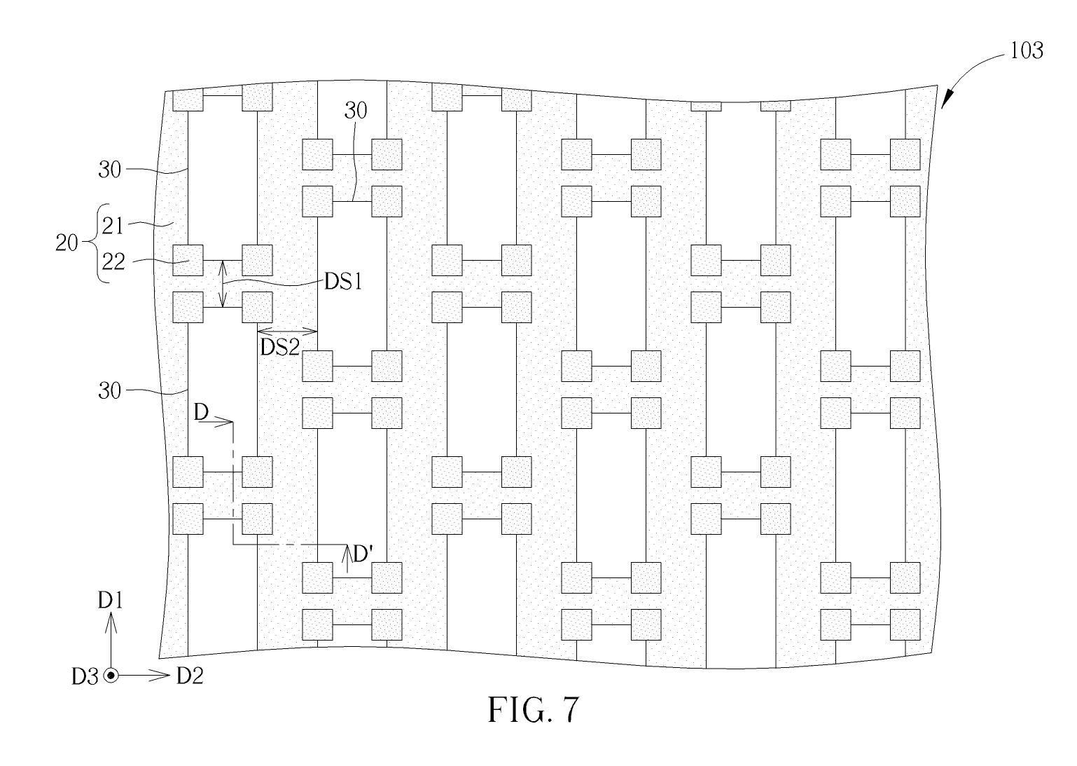

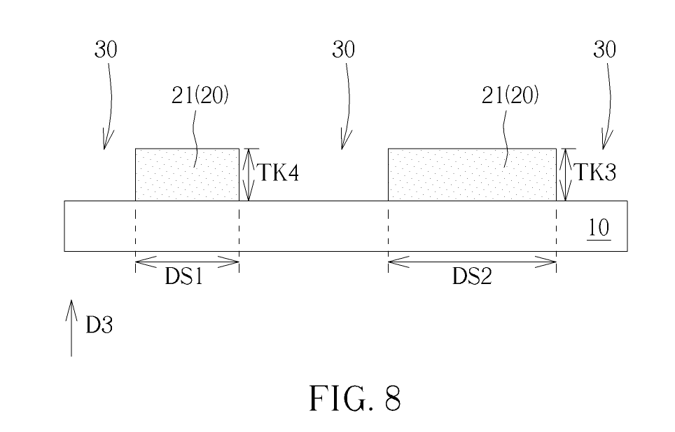

Please refer to FIG. 7 and FIG. 8. FIG. 7 is a top-view diagram illustrating a photomask 103 according to a third embodiment of the present invention. FIG. 8 is a cross-sectional diagram taken along a line D-D′ in FIG. 7. As shown in FIG. 7 and FIG. 8, the difference between the photomask 103 in this embodiment and the photomask in the first embodiment is that each of the openings 30 in the photomask 103 of this embodiment may be a dodecagon, and the second patterned layer 22 is formed at four concave corners of each of the openings 30. Therefore, another part of the patterned absorber layer 20 disposed between the two adjacent openings 30 in the first direction D1 may have a fourth thickness TK4, and the fourth thickness TK4 is equal to the third thickness TK3. In other words, the second patterned layer 22 in this embodiment does not completely cover the edge of each of the openings which is adjacent to another opening in the first direction D1, and a part of the first patterned layer 21 disposed at the edges of each of the openings 30 and disposed between the two adjacent openings 30 in the first direction D1 is not covered by the second patterned layer 22.

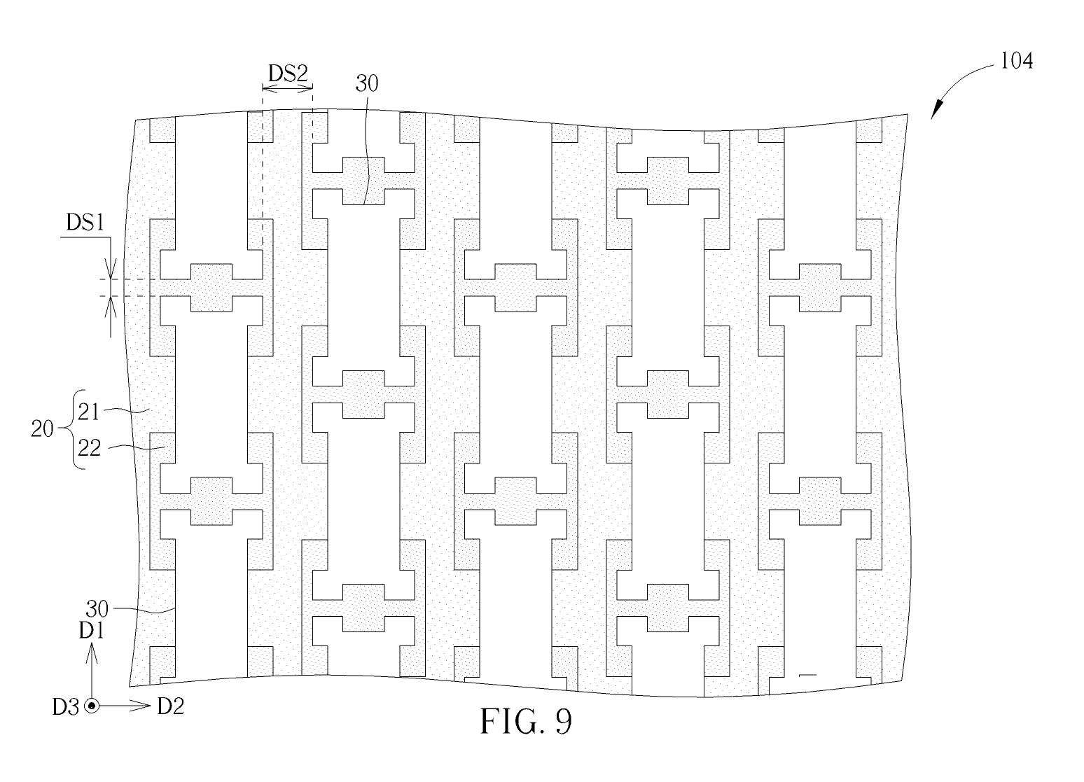

Please refer to FIG. 9. FIG. 9 is a top-view diagram illustrating a photomask 104 according to a fourth embodiment of the present invention. As shown in FIG. 9, the difference between the photomask 104 in this embodiment and the photomask in the first embodiment is that each of the openings 30 in the photomask 103 of this embodiment may be a twenty-gon, four convex rectangles are located at four corners of each of the openings 30, and the second patterned layer 22 surrounds the four corners of each of the openings 30. It is worth noting that the shape of the openings in the photomask of the present invention is not limited to the shapes described in the above-mentioned embodiments, and the openings with other regular or irregular shapes may also be used in the embodiments of the present invention.

To summarize the above descriptions, in the photomask of the present invention, the thickness of at least a part of the patterned absorber layer disposed between two adjacent openings which are relatively closer to each other is different from the thickness of at least a part of the patterned absorber layer disposed between two adjacent openings which are relatively far from each other. The patterned absorber layer having the different thickness distribution in the different regions may be used to modify the focus length at the region between two adjacent openings in the exposure process, the problem of unable to form the pattern corresponding to regions between adjacent openings after the exposure and the develop processes when the adjacent openings are extremely close to one another may be avoided accordingly, and the purpose of enhancing the resolution of the photolithographic process may be achieved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A photomask, comprising:
a substrate; and
a patterned absorber layer disposed on the substrate; and
a plurality of openings, each of the openings penetrating the patterned absorber layer and exposing a part of the substrate, wherein
at least two of the openings are disposed adjacent to each other in a first direction,
at least a part of the patterned absorber layer disposed between the two adjacent openings in the first direction has a first thickness,
a part of the patterned absorber layer disposed at two opposite edges of each of the openings in a second direction different from the first direction has a second thickness, and
another part of the patterned absorber layer disposed at the two opposite edges of each of the openings in the second direction has a third thickness, wherein the first thickness is equal to the second thickness, and the first thickness is different from the third thickness.

2. The photomask according to claim 1, wherein the first thickness is larger than the third thickness.

3. The photomask according to claim 1, wherein at least two of the openings are disposed adjacent to each other in the second direction, and a distance between the two adjacent openings in the first direction is smaller than a distance between the two adjacent openings in the second direction.

4. The photomask according to claim 1, wherein the patterned absorber layer comprises:
a first patterned layer disposed on the substrate; and
a second patterned layer disposed on the first patterned layer, wherein the second patterned layer is partly disposed between the two adjacent openings in the first direction and partly disposed at the two opposite edges of each of the openings in the second direction.

5. The photomask according to claim 4, wherein a material of the first patterned layer and a material of the second patterned layer are the same.

6. The photomask according to claim 4, wherein a material of the first patterned layer is different from a material of the second patterned layer.

7. The photomask according to claim 6, wherein the first patterned layer comprises molybdenum silicide and the second patterned layer comprises chromium.

8. The photomask according to claim 4, wherein the first patterned layer surrounds each of the openings, and the second patterned layer is disposed at only a part of edges of each of the openings.

9. The photomask according to claim 8, wherein a part of the first patterned layer disposed at the edges of the openings and disposed between the two adjacent openings in the second direction is not covered by the second patterned layer.

10. The photomask according to claim 4, wherein a width of the first patterned layer disposed between the two adjacent openings in the first direction is equal to a width of the second patterned layer disposed between the two adjacent openings in the first direction.

11. The photomask according to claim 4, wherein a width of the second patterned layer disposed between the two adjacent openings in the first direction is larger than a width of the first patterned layer disposed between the two adjacent openings in the first direction.

12. The photomask according to claim 1, wherein the patterned absorber layer disposed between the two adjacent openings in the first direction only has the first thickness.

13. The photomask according to claim 1, wherein another part of the patterned absorber layer disposed between the two adjacent openings in the first direction has a fourth thickness, and the fourth thickness is equal to the third thickness.
